(19) United States
(12) Patent Application Publication
(10) Pub. No.: US 2026/0173612 A1
(43) Pub. Date: Jun. 18, 2026

(54) DISPLAY DEVICE AND MANUFACTURING METHOD

(71) Applicant: LG Display Co., Ltd., Seoul (KR)

(72) Inventors: Jinhyeon YUN, Paju-si (KR); DoYoung KWAK, Paju-si (KR); Youngsuk HWANG, Paju-si (KR); Bongseok CHOI, Paju-si (KR)

(73) Assignee: LG Display Co., Ltd., Seoul (KR)

(21) Appl. No.: 19/326,839

(22) Filed: Sep. 12, 2025

(30) Foreign Application Priority Data
Dec. 18, 2024 (KR) 10-2024-0189625

(51) Int. Cl. H10H 29/39; H10H 29/01

(52) U.S. Cl. CPC H10H 29/39; H10H 29/012

(57) ABSTRACT

A display device and a method of manufacturing the display device are discussed. The display device can include a barrier structure having a first portion, a second portion and a third portion. The first portion is positioned in a first outer region of a first light-emitting device. The second portion is positioned in a second outer region of a second light-emitting device and extends parallel to the first portion. The third portion is positioned between the first light-emitting device and the second light-emitting device and extends parallel to the first portion. By including this barrier structure, the light-emitting device can be easily fixed while also allowing for convenient repair.

### CROSS-REFERENCE TO RELATED APPLICATION

This application claims priority to Korean Patent Application No. 10-2024-0189625, filed in the Republic of Korea on Dec. 18, 2024, which is hereby incorporated by reference for all purposes as if fully set forth herein.

### BACKGROUND

### Field

Embodiments of the present disclosure relate to a display device and a method of manufacturing the same.

### Discussion of the Related Art

As the information society advances, the demand for display devices for displaying images has increased in various forms. Recently, various types of display devices, such as liquid crystal display (LCD) devices and organic light-emitting display (OLED) devices, have been utilized.

A display device can include a plurality of light-emitting devices. During the process of arranging the plurality of light-emitting devices, defective light-emitting devices can be detected. The defective light-emitting devices can be repaired by an operator.

### SUMMARY OF THE DISCLOSURE

Embodiments of the present disclosure can provide a display device capable of securely fixing a light-emitting device using an intermediate material.

Embodiments of the present disclosure can provide a display device in which defective light-emitting devices can be replaced through a repair process.

Embodiments of the present disclosure can provide a display device that enables process optimization by fixing light-emitting devices with an intermediate material while allowing defective light-emitting devices to be easily repaired.

The technical objects of embodiments of the present disclosure are not limited to those explicitly mentioned herein, and other objects not explicitly stated will be readily understood by those skilled in the art from the following descriptions.

Embodiments of the present disclosure can provide a display device comprising a substrate; a first connection electrode disposed on the substrate and including a metal material; a first light-emitting device disposed on the first connection electrode; a second connection electrode disposed on the substrate and including the metal material; a second light-emitting device disposed on the second connection electrode; a first intermediate material disposed on the first connection electrode, including a thermosetting material that hardens upon exposure to heat or light, and disposed in contact with a portion of the first light-emitting device; a second intermediate material disposed on the second connection electrode, including the thermosetting material, and disposed in contact with a portion of the second light-emitting device; and a barrier structure including a first portion positioned in a first outer region of the first light-emitting device, a second portion positioned in a second outer region of the second light-emitting device and extending parallel to the first portion, and a third portion positioned between the first and second light-emitting devices and extending parallel to the first portion.

Embodiments of the present disclosure can provide a method of manufacturing a display device, comprising a mounting step in which a light-emitting device attached to a stamp comes into contact with an intermediate material, and a portion of the light-emitting device is embedded in an inner side of the intermediate material; a voltage supply step in which voltage is supplied to the light-emitting device through a connection electrode, and the light-emitting device emits light; and an intermediate material curing step in which the intermediate material hardens upon receiving light emitted from the light-emitting device.

According to embodiments of the present disclosure, a display device capable of securely fixing a light-emitting device using an intermediate material can be provided.

According to embodiments of the present disclosure, a display device in which defective light-emitting devices can be replaced through a repair process can be provided.

According to embodiments of the present disclosure, a display device that enables process optimization by fixing light-emitting devices with an intermediate material while allowing defective light-emitting devices to be easily repaired can be provided.

The effects of embodiments of the present disclosure are not limited to those described above, and other effects not explicitly mentioned will be apparent to those skilled in the art from the following descriptions.

### BRIEF DESCRIPTION OF THE DRAWINGS

The present disclosure will be more fully understood from the following detailed description and the accompanying drawings. The detailed description and drawings are provided for illustrative purposes only and are not intended to limit the scope of the present disclosure.

FIG. 1 is a system configuration diagram of a display device according to embodiments of the present disclosure.

FIG. 2 is a diagram of a light-emitting device according to embodiments of the present disclosure.

FIG. 3 is a cross-sectional view of a display panel and a light-emitting device according to embodiments of the present disclosure.

FIG. 4 is a cross-sectional view of a display panel and a light-emitting device according to embodiments of the present disclosure.

FIG. 5 and FIG. 6 are cross-sectional views of the manufacturing process for a display panel and a light-emitting device according to embodiments of the present disclosure.

FIG. 7 and FIG. 8 are cross-sectional views of the manufacturing process for a display panel and a light-emitting device according to embodiments of the present disclosure.

FIG. 9 is a cross-sectional view of a display panel and a light-emitting device according to embodiments of the present disclosure.

FIG. 10 is a cross-sectional view of a light-emitting device and a barrier structure according to embodiments of the present disclosure.

FIG. 11 and FIG. 12 are diagrams of a reflective layer according to embodiments of the present disclosure.

FIG. 13 is a diagram of a reflective layer according to embodiments of the present disclosure.

FIG. 14 is a flowchart illustrating a method of manufacturing a display device according to embodiments of the present disclosure.

### DETAILED DESCRIPTION OF THE EMBODIMENTS

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description can make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Various embodiments of the present disclosure will be described in detail with reference to the accompanying drawings. All the components of each display device according to all embodiments of the present disclosure are operatively coupled and configured.

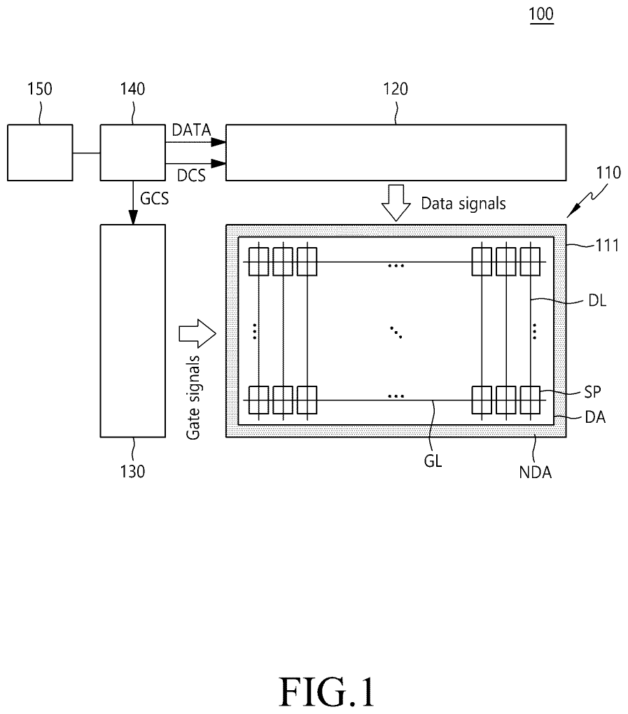

FIG. 1 is a system configuration diagram of a display device 100 according to embodiments of the present disclosure.

Referring to FIG. 1, the display device 100 according to embodiments of the present disclosure can include a display panel 110 and a display driving circuit as components for image display. The display driving circuit is a circuit for driving the display panel 110 and can include a data driving circuit 120, a gate driving circuit 130, and a display controller 140.

The display panel 110 can include a substrate 111 and a plurality of sub-pixels SP disposed on the substrate 111.

The substrate 111 of the display panel 110 can include a display area DA capable of displaying images and a non-display area NDA located outside the display area DA.

A plurality of sub-pixels SP for image display can be arranged in the display area DA, and the non-display area NDA can include a pad area PA positioned in a first direction from the display area DA.

In the display panel 110 according to embodiments of the present disclosure, the non-display area NDA can be very small. In this disclosure, the non-display area NDA is also referred to as a “bezel.”

Various types of signal lines for driving the plurality of sub-pixels SP can be disposed on the substrate 111 of the display panel 110.

The display device 100 according to embodiments of the present disclosure can be a liquid crystal display (LCD) or a self-emissive display in which the display panel 110 emits light on its own. When the display device 100 is a self-emissive display, each of the plurality of sub-pixels SP can include a light-emitting device.

For example, the display device 100 according to embodiments of the present disclosure can be an organic light-emitting display in which the light-emitting device is implemented as an organic light-emitting diode (OLED). As another example, the display device 100 can be an inorganic light-emitting display in which the light-emitting device is implemented as an inorganic light-emitting diode. As yet another example, the display device 100 can be a quantum dot display in which the light-emitting device is implemented as a quantum dot, which is a semiconductor crystal that emits light on its own.

The structure of each sub-pixel SP can vary depending on the type of display device 100. For example, when the display device 100 is a self-emissive display in which each sub-pixel SP emits light on its own, each sub-pixel SP can include a light-emitting device, at least one transistor, and at least one capacitor.

Various types of signal lines can include a plurality of data lines DL that transmit data signals (also referred to as data voltages or image signals) and a plurality of gate lines GL that transmit gate signals (also referred to as scan signals).

The data driving circuit 120 is a circuit for driving the plurality of data lines DL and can output data signals to the plurality of data lines DL.

The data driving circuit 120 can receive digital image data DATA from the display controller 140, convert the received image data DATA into analog data signals, and output the analog data signals to the plurality of data lines DL.

The data driving circuit 120 can be connected to one side (e.g., an upper side or a lower side) of the display panel 110. Alternatively, depending on the driving method or panel design, the data driving circuit 120 can be connected to both sides (e.g., the upper and lower sides) of the display panel 110 or to two or more sides among the four sides of the display panel 110.

The data driving circuit 120 can be connected to the outer region of the display area DA of the display panel 110. Alternatively, it can be disposed in the display area DA of the display panel 110.

The gate driving circuit 130 is a circuit for driving the plurality of gate lines GL and can output gate signals to the plurality of gate lines GL.

The gate driving circuit 130 can receive a first gate voltage corresponding to a turn-on level voltage and a second gate voltage corresponding to a turn-off level voltage, along with various gate driving control signals GCS, to generate gate signals and supply the generated gate signals to the plurality of gate lines GL.

The display controller 140 is a device for controlling the data driving circuit 120 and the gate driving circuit 130 and can control the driving timing of the plurality of data lines DL and the plurality of gate lines GL.

The display controller 140 can supply a data driving control signal DCS to the data driving circuit 120 to control the data driving circuit 120 and supply a gate driving control signal GCS to the gate driving circuit 130 to control the gate driving circuit 130.

The display controller 140 can receive input image data from a host system 150 and supply image data DATA to the data driving circuit 120 based on the input image data.

The display controller 140 can be implemented as a separate component from the data driving circuit 120 or can be integrated with the data driving circuit 120 as an integrated circuit.

The display controller 140 can be a timing controller used in conventional display technology, a control device that includes a timing controller and performs additional control functions, a control device separate from the timing controller, or a circuit within a control device.

The display controller 140 can be mounted on a printed circuit board (PCB) or a flexible printed circuit (FPC) and can be electrically connected to the data driving circuit 120 and the gate driving circuit 130 via the printed circuit board (PCB) or the flexible printed circuit (FPC).

The display device 100 according to embodiments of the present disclosure can provide a touch sensing function in addition to an image display function. To this end, the display device 100 can include a touch sensor and a touch sensing circuit that detects whether a touch has occurred by a touch object, such as a finger or a pen, or detects the touch position by sensing the touch sensor.

The touch sensing circuit can include a touch driving circuit that drives and senses the touch sensor to generate and output touch sensing data, and a touch controller that detects a touch event or determines the touch position based on the touch sensing data.

The touch sensor can include a plurality of touch electrodes. The touch sensor can further include a plurality of touch lines for electrically connecting the plurality of touch electrodes to the touch driving circuit.

The touch driving circuit can supply a touch driving signal to at least one of the plurality of touch electrodes and can sense at least one of the plurality of touch electrodes to generate touch sensing data.

The touch driving circuit and the touch controller included in the touch sensing circuit can be implemented as separate devices or as a single device. Additionally, the touch driving circuit and the data driving circuit can be implemented as separate devices or as a single device.

The display device 100 can further include a power supply circuit that supplies various power sources to the display driving circuit and/or the touch sensing circuit.

The display device 100 according to embodiments of the present disclosure can further include electronic devices such as a camera (image sensor) or a sensing sensor. For example, the sensing sensor can be a sensor that detects an object or a human body by receiving light such as infrared light, ultrasound, or ultraviolet light.

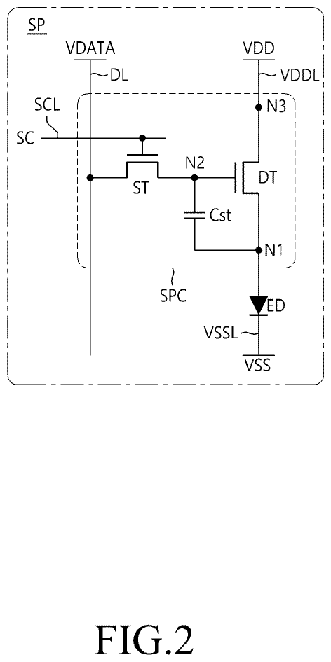

FIG. 2 is a diagram illustrating a sub-pixel SP of a display device according to embodiments of the present disclosure. Each sub-pixel SP of the display device (e.g., 100) according to the embodiments of the present disclosure can have the configuration shown in FIG. 2.

Referring to FIG. 2, each of the plurality of sub-pixels SP can include a light-emitting device ED and a sub-pixel circuit SPC for driving the light-emitting device ED.

The sub-pixel circuit SPC can include a plurality of pixel driving transistors and at least one capacitor for driving the light-emitting device ED. In this disclosure, the sub-pixel circuit SPC can drive the light-emitting device ED by supplying a driving current to the light-emitting device ED at a predetermined timing. The light-emitting device ED can be driven by the driving current and emit light.

The plurality of pixel driving transistors can include a driving transistor DT for driving the light-emitting device ED and a scan transistor ST that turns on or off in response to a scan signal SC.

The driving transistor DT can supply a driving current to the light-emitting device ED.

The scan transistor ST can be configured to control the electrical state of a corresponding node in the sub-pixel circuit SPC or to control the state or operation of the driving transistor DT.

The at least one capacitor can include a storage capacitor Cst that maintains a constant voltage during a frame period.

To drive the sub-pixel SP, a data signal VDATA, which is an image signal, and a scan signal SC, which is a gate signal, can be applied to the sub-pixel SP. Additionally, to drive the sub-pixel SP, a common pixel driving voltage, including a driving voltage VDD and a reference voltage VSS, can be applied to the sub-pixel SP.

The light-emitting device ED can be an organic light-emitting diode (OLED), an inorganic light-emitting diode (LED), or a quantum dot light-emitting device. For example, when the light-emitting device ED is an OLED, a light-emitting device intermediate layer EL in the light-emitting device ED can include an organic material-containing light-emitting device intermediate layer EL.

The driving transistor DT can be a driving transistor for supplying a driving current to the light-emitting device ED. The driving transistor DT can be connected between a driving voltage line VDDL and the light-emitting device ED.

The driving transistor DT can include a first node N1 electrically connected to the light-emitting device ED, a second node N2 to which the data signal VDATA can be applied, and a third node N3 to which the driving voltage VDD is applied from the driving voltage line DVL.

In the driving transistor DT, the second node N2 can be a gate node, the first node N1 can be a source node or a drain node, and the third node N3 can be a drain node or a source node. Hereinafter, for convenience of description, an example is given where, in the driving transistor DT, the second node N2 is a gate node, the first node N1 is a source node, and the third node N3 is a drain node.

The scan transistor ST included in the sub-pixel circuit SPC illustrated in FIG. 2 can be a switching transistor for delivering the data signal VDATA, which is an image signal, to the second node N2, which is the gate node of the driving transistor DT.

The scan transistor ST can be turned on and off by a scan signal SC, which is a gate signal applied through a scan line SCL, which is one type of gate line GL. This allows the scan transistor ST to control the electrical connection between the second node N2 of the driving transistor DT and the data line DL. The drain electrode or source electrode of the scan transistor ST can be electrically connected to the data line DL, the source electrode or drain electrode of the scan transistor ST can be electrically connected to the second node N2 of the driving transistor DT, and the gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to or corresponding to the first node N1 of the driving transistor DT and a second capacitor electrode electrically connected to or corresponding to the second node N2 of the driving transistor DT.

The storage capacitor Cst is an external capacitor intentionally designed outside the driving transistor DT, rather than a parasitic capacitor (e.g., Cgs, Cgd), which is an internal capacitor that can exist between the first node N1 and the second node N2 of the driving transistor DT.

Each of the driving transistor DT and the scan transistor ST can be an n-type transistor or a p-type transistor.

The display panel 110 can have a top-emission structure or a bottom-emission structure.

When the display panel 110 has a top-emission structure, at least a portion of the sub-pixel circuit SPC can overlap with at least a portion of the light-emitting device ED in the vertical direction. Conversely, when the display panel 110 has a bottom-emission structure, the sub-pixel circuit SPC may not overlap with the light-emitting device ED in the vertical direction.

As illustrated in FIG. 2, the sub-pixel circuit SPC can have a 2T1C structure, including two transistors DT and ST and one capacitor Cst. In some cases, the sub-pixel circuit SPC can further include at least one additional transistor or at least one additional capacitor.

For example, the sub-pixel circuit SPC can have an 8T1C structure including eight transistors and one capacitor. As another example, the sub-pixel circuit SPC can have a 6T2C structure including six transistors and two capacitors. As yet another example, the sub-pixel circuit SPC can have a 7T1C structure including seven transistors and one capacitor.

Depending on the structure of the sub-pixel circuit SPC, the type and number of gate lines supplying the gate signal to the sub-pixel SP can vary.

Additionally, depending on the structure of the sub-pixel circuit SPC, the type and number of common pixel driving voltages supplied to the sub-pixel SP can vary.

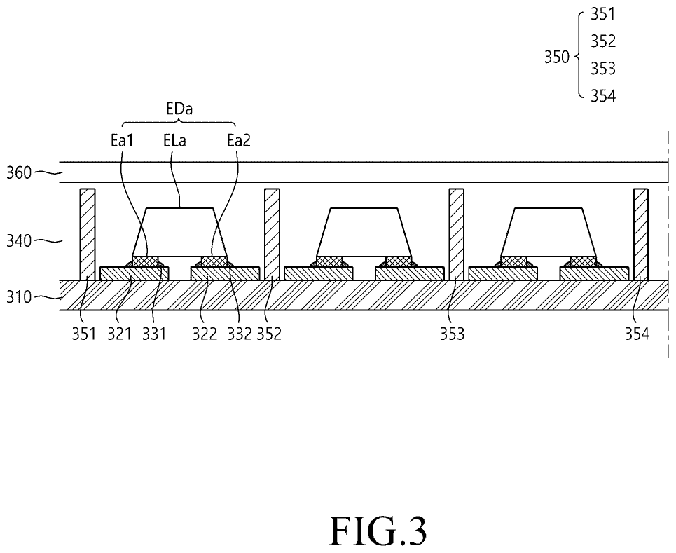

FIG. 3 is a cross-sectional view of the display panel 110 and the light-emitting device according to embodiments of the present disclosure.

Referring to FIG. 3, the lower substrate 310 can be positioned at the lowest part of the display panel 110 illustrated in FIG. 1.

Connection electrodes 321 and 322 can be disposed on the lower substrate 310. The connection electrodes 321 and 322 can include a metal material. The connection electrodes 321 and 322 can include a conductive material. The connection electrodes 321 and 322 can include a transparent material. For example, the connection electrodes 321 and 322 can include a metal material having conductivity, and the metal material can be a transparent material. For example, the connection electrodes 321 and 322 can be made of ITO or IZO.

Intermediate materials 331 and 332 can be disposed on the connection electrodes 321 and 322. The intermediate materials 331 and 332 can include a thermosetting material. The intermediate materials 331 and 332 can harden upon exposure to heat or light. For example, when the intermediate materials 331 and 332 are exposed to a predetermined electromagnetic energy, a chemical change can occur in the intermediate materials. In this case, the intermediate materials 331 and 332 can transition from a liquid state to a solid state. The range of electromagnetic energy can be 500 to 1000 kJ/mol.

The light-emitting devices EDa can include a light-emitting layer ELa, a first electrode Ea1, and a second electrode Ea2.

The light-emitting layer ELa can be a layer that emits light. The light-emitting layer ELa can be formed as a single layer or as a multiple quantum well structure. The light-emitting layer ELa can include an electron-supplying layer and a hole-supplying layer.

The first electrode Ea1 can be a pixel electrode or an anode electrode. The first electrode Ea1 can include a metal material. For example, the first electrode Ea1 can be a transparent metal oxide such as ITO, IGZO, or IZO.

The second electrode Ea2 can be a pixel electrode or an anode electrode. The second electrode Ea2 can include a metal material. For example, the second electrode Ea2 can be a transparent metal oxide such as ITO, IGZO, or IZO.

A barrier structure 350 can be disposed on the lower substrate 310. The barrier structure 350 can reflect or absorb light. The barrier structure 350 can be positioned between adjacent light-emitting devices EDa. A detailed description of the barrier structure 350 will be provided below.

An insulating layer 340 can be disposed to cover the barrier structure 350 and the light-emitting devices EDa. The insulating layer 340 can include an insulating material and can include an organic material. The insulating layer 340 can fix the position of the light-emitting devices EDa. The upper surface of the insulating layer 340 can be formed to be flat.

A protective layer 360 can be disposed on the insulating layer 340. The protective layer 360 can include an insulating material or an inorganic material. Alternatively, the protective layer 360 can be a glass substrate. The protective layer 360 can protect the light-emitting devices EDa from external factors.

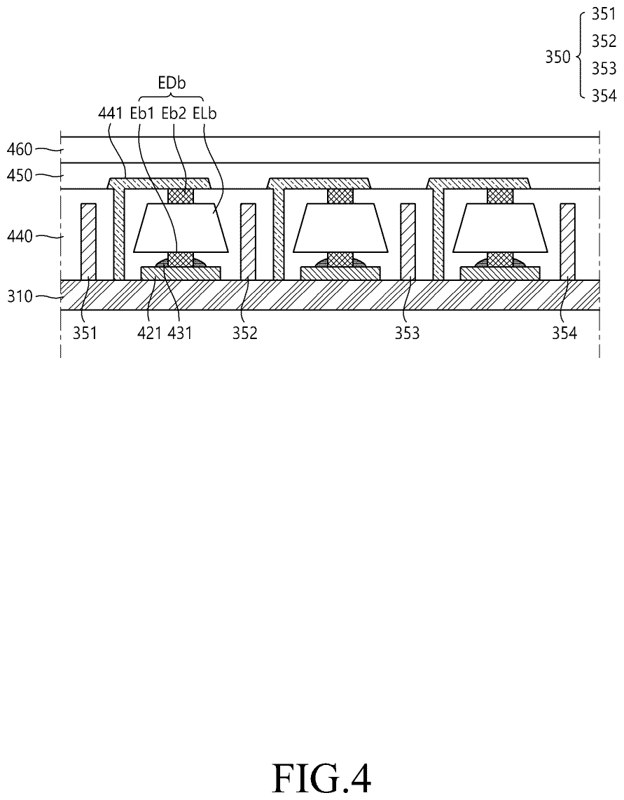

FIG. 4 is a cross-sectional view of the display panel 110 and the light-emitting device according to embodiments of the present disclosure.

Referring to FIG. 4, the lower substrate 310 can be positioned at the lowest part of the display panel 110 illustrated in FIG. 1.

Connection electrodes 421 can be disposed on the lower substrate 310. The connection electrodes 421 can supply a voltage to the light-emitting devices EDb to drive them.

An intermediate material 431 can be disposed on the connection electrodes 421. The characteristics of the intermediate material 431 illustrated in FIG. 4 can be the same as those of the intermediate material 331 illustrated in FIG. 3.

The light-emitting devices EDb can be disposed on the connection electrodes 421. The light-emitting devices EDb can include a first electrode Eb1, a light-emitting layer ELb, and a second electrode Eb2. The first electrode Eb1 of the light-emitting device can be positioned closer to the lower substrate 310 than the second electrode Eb2. The light-emitting layer ELb can be disposed on the first electrode Eb1. The second electrode Eb2 can be disposed on the light-emitting layer ELb.

The barrier structure 350 can be positioned around the light-emitting devices EDb. The barrier structure 350 can reflect or absorb light.

A first insulating layer 440 can be disposed to cover the light-emitting devices EDb and the barrier structure 350. The first insulating layer 440 can include an organic material. The upper surface of the first insulating layer 440 can be flat.

A base voltage line 441 can be disposed in the first insulating layer 440. The base voltage line 441 can be electrically connected to the lower substrate 310 through a contact hole formed in the first insulating layer 440. The base voltage line 441 can receive a base voltage from the lower substrate 310. The base voltage line 441 can be electrically connected to the second electrode Eb2.

A second insulating layer 450 can be disposed on the first insulating layer 440. The second insulating layer 450 can include an inorganic material or an organic material.

A protective layer 460 can be disposed on the second insulating layer 450. The protective layer 460 can include an insulating material or an inorganic material. Alternatively, the protective layer 460 can be a glass substrate. The protective layer 460 can protect the light-emitting devices EDb from external factors.

Hereinafter, a portion of the manufacturing process of the light-emitting devices EDa and EDb illustrated in FIG. 3 and FIG. 4 according to embodiments of the present disclosure will be described.

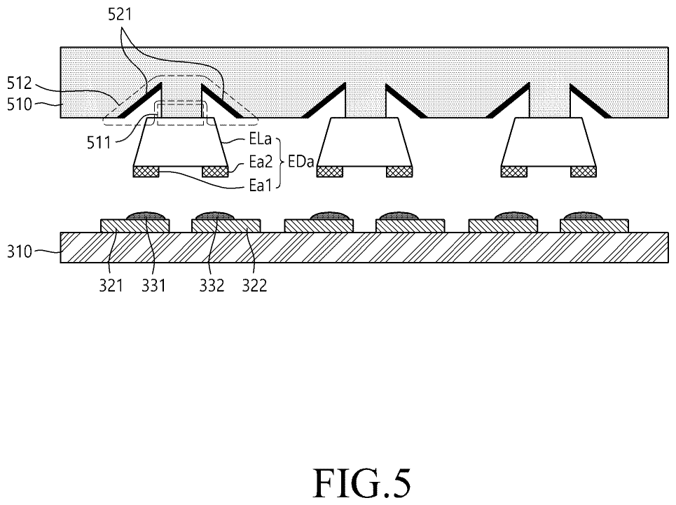

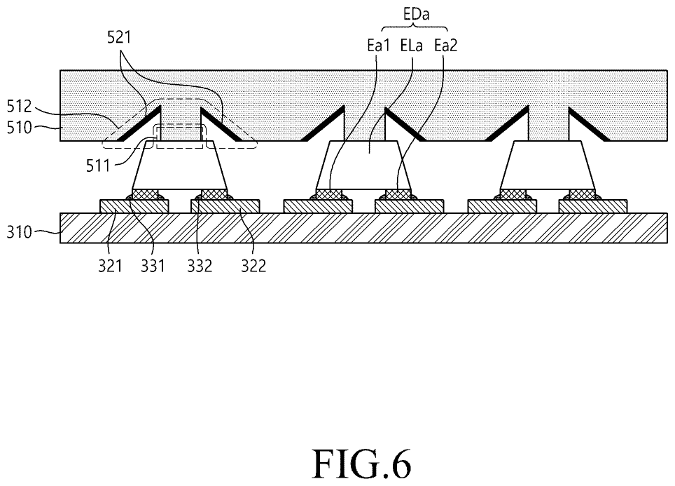

FIG. 5 and FIG. 6 are cross-sectional views of the display panel 110 and the light-emitting device according to embodiments of the present disclosure.

Referring to FIG. 5, the lower substrate 310 can be positioned at the lowest part of the display panel 110 illustrated in FIG. 1.

The lower substrate 310 illustrated in FIG. 5 can include the substrate 111 illustrated in FIG. 1.

The lower substrate 310 illustrated in FIG. 5 can include transistors ST and DT and a storage capacitor Cst, as illustrated in FIG. 2.

Referring to FIG. 5, connection electrodes 321 and 322 can be disposed on the lower substrate 310. The connection electrodes 321 and 322 can include a metal material. The connection electrodes 321 and 322 can include a conductive material. The connection electrodes 321 and 322 can include a transparent material. For example, the connection electrodes 321 and 322 can include a metal material having conductivity, and the metal material can be a transparent material. For example, the connection electrodes 321 and 322 can be made of ITO or IZO.

Intermediate materials 331 and 332 can be disposed on the connection electrodes 321 and 322.

The intermediate materials 331 and 332 can include a thermosetting material. The intermediate materials 331 and 332 can harden when exposed to heat or light. For example, when the intermediate materials 331 and 332 are exposed to a predetermined electromagnetic energy, a chemical change can occur in the intermediate materials. In this case, the intermediate materials 331 and 332 can transition from a liquid state to a solid state. The range of electromagnetic energy can be 500 to 1000 kJ/mol.

The intermediate materials 331 and 332 can be acrylate-based (urethane acrylate, epoxy acrylate, polyester acrylate), epoxy-based (diglycidyl ether epoxy, novolac epoxy, polyol epoxy), polyester-based (unsaturated polyester, polyurethane polyester), or polyurethane-based (aliphatic polyurethane, aromatic polyurethane). Additionally, the intermediate materials 331 and 332 can include a resin material. For example, the intermediate materials 331 and 332 can include polymethyl methacrylate, polyurethane, epoxy, polyester, or polyisoprene.

The intermediate materials 331 and 332 can include a non-conductive material. However, they can also include a conductive material. For example, the intermediate materials 331 and 332 can include polyacetylene, polyaniline, polypyrrole, polyphenylene, polyphenylene vinylene, or polythiophene. Additionally, the intermediate materials 331 and 332 can include inorganic conductive materials such as silver nanoparticles or carbon black.

The intermediate materials 331 and 332 can have a convex hemispherical shape.

The light-emitting devices EDa can be attached to a stamp 510. Subsequently, the light-emitting devices EDa can be placed on the intermediate materials 331 and 332. This process can be referred to as an “LED transfer process” or an “LED pick-and-place process.”

The light-emitting devices EDa can include a light-emitting layer ELa, a first electrode Ea1, and a second electrode Ea2.

The light-emitting layer ELa can be a layer that emits light. The light-emitting layer ELa can be formed as a single layer or a multiple quantum well structure. The light-emitting layer ELa can include an electron-supplying layer and a hole-supplying layer.

The first electrode Ea1 can be a pixel electrode or an anode electrode. The first electrode Ea1 can include a metal material. For example, the first electrode Ea1 can be a transparent metal oxide such as ITO, IGZO, or IZO.

The second electrode Ea2 can be a pixel electrode or an anode electrode. The second electrode Ea2 can include a metal material. For example, the second electrode Ea2 can be a transparent metal oxide such as ITO, IGZO, or IZO.

The light-emitting devices EDa can be attached to the stamp 510. Referring to FIG. 5, the stamp 510 can include bonding portions 511, and the light-emitting devices EDa can be attached to the bonding portions 511 of the stamp 510. Referring to FIG. 6, the stamp 510 can move toward the lower substrate 310. Accordingly, the light-emitting devices EDa can come into contact with the intermediate materials 331 and 332. Referring to FIG. 6, the connection electrodes 321 and 322 electrically connected to the light-emitting devices EDa can be observed.

Referring to FIG. 6, after the light-emitting devices EDa are electrically connected to the connection electrodes 321 and 322, a voltage for driving the light-emitting devices EDa can be supplied to the first electrode Ea1 and the second electrode Ea2. For example, after the stamp 510 process is completed, the light-emitting devices EDa can emit light while still attached to the stamp 510.

A reflective layer 521 can be disposed between the stamp 510 and the light-emitting devices EDa. The reflective layer 521 can be positioned on the outer periphery of the bonding portion 511. The bonding portion 511 can have a protruding shape, and a peripheral area 512 can be located around the bonding portion 511. The peripheral area 512 can be a recessed groove area.

Referring to FIG. 5, the bonding portion 511 can have a cylindrical shape. The peripheral area 512 can be shaped as a cylinder centered around the bonding portion 511. In the cross-sectional view of FIG. 5, the left side of the bonding portion 511 is observed to have a right-angled triangular groove near its lower part. Similarly, the right side of the bonding portion 511 also has a right-angled triangular groove near its lower part. These right-angled triangular grooves can be formed around the entire periphery of the bonding portion 511.

The reflective layer 521 can be disposed in the peripheral area 512. The reflective layer 521 can be located in the peripheral area 512 and positioned at the lower portion of the stamp 510. Referring to FIG. 5, the reflective layer 521 may not overlap with the bonding portion 511.

The reflective layer 521 can reflect light emitted from the light-emitting devices EDa. The reflective layer 521 can include a material capable of reflecting light. For example, the reflective layer 521 can be a metal material, but it is not limited thereto.

The light emitted from the light-emitting devices EDa can be reflected by the reflective layer 521 in a downward direction. The reflected light can travel toward the intermediate materials 331 and 332. The reflected light can pass through the light-emitting devices EDa, the light-emitting layer ELa, the first electrode Ea1, and the second electrode Ea2.

When the reflected light reaches the intermediate materials 331 and 332, they can transition from a liquid state to a solid state. When the reflected light reaches the intermediate materials 331 and 332, their viscosity can change from low to high. Once the intermediate materials 331 and 332 harden, the light-emitting devices EDa can be fixed in position by the intermediate materials 331 and 332. Referring to FIG. 6, the first electrode Ea1 and the second electrode Ea2 of the light-emitting devices EDa can be electrically connected to the connection electrodes 321 and 322. For example, the light-emitting devices EDa can be electrically connected to the connection electrodes 321 and 322 while their positions remain stably fixed.

The above process can be summarized as follows. The light-emitting devices EDa can come into contact with the intermediate materials 331 and 332 on the connection electrodes 321 and 322 via the stamp 510. In this case, the first electrode Ea1 and the second electrode Ea2 can penetrate into the inner side of the intermediate materials 331 and 332, thereby allowing the light-emitting devices EDa to be electrically connected to the connection electrodes 321 and 322. Subsequently, the light-emitting devices EDa can emit light. The emitted light can be reflected by the reflective layer 521 toward the lower part of the light-emitting devices EDa, which can harden the intermediate materials 331 and 332. As a result, the light-emitting devices EDa can remain electrically connected to the connection electrodes 321 and 322 while being securely fixed in position.

If the light-emitting device EDa is not electrically connected to the connection electrodes 321 and 322, the light-emitting device EDa may not emit light. If the light-emitting device EDa does not emit light, the intermediate materials 331 and 332 overlapping with the light-emitting device EDa may not harden. For example, if the light-emitting device EDa itself is defective or if it is abnormally connected to the connection electrodes 321 and 322, its position may not be fixed. Subsequently, an unfixed light-emitting device EDa can be fixed through a separate repair process. However, the repaired light-emitting device EDa may not overlap with the intermediate materials 331 and 332.

The light-emitting device EDa illustrated in FIG. 5 and FIG. 6 can be a flip-type light-emitting device in which both the first electrode Ea1 and the second electrode Ea2 are disposed on one side of the device. Hereinafter, a vertical-type light-emitting device, in which the first electrode Ea1 is disposed on one side and the second electrode Ea2 is disposed on the opposite side, will be described.

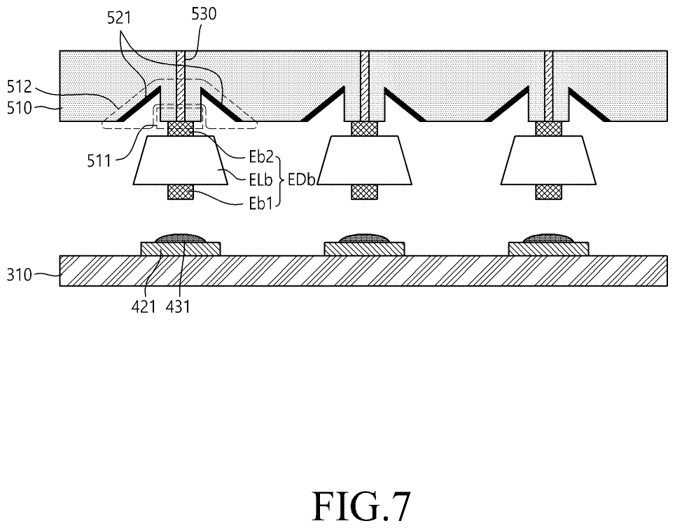

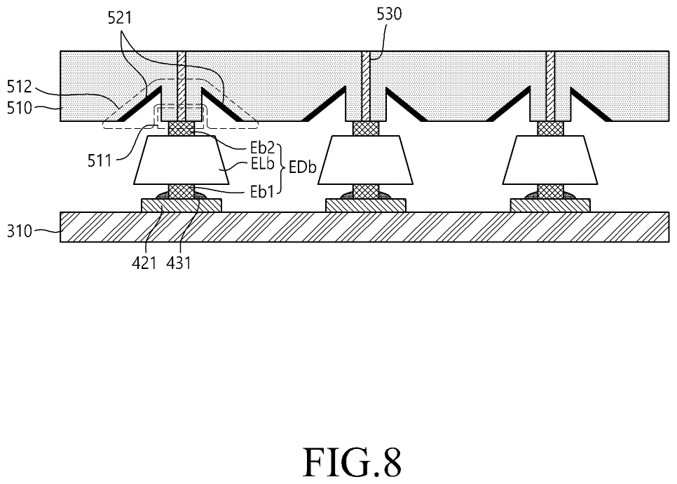

FIG. 7 and FIG. 8 are cross-sectional views of the display panel 110 and the light-emitting device according to embodiments of the present disclosure.

Referring to FIG. 7, connection electrodes 421 can be disposed on the lower substrate 310. The connection electrodes 421 can be electrodes to which a high-potential voltage is supplied. However, depending on the design, the connection electrodes 421 can also be electrodes to which a low-potential voltage is supplied.

Intermediate materials 431 can be disposed on the connection electrodes 421. The characteristics of the intermediate material 431 illustrated in FIG. 7 can be the same as those of the intermediate materials 331 and 332 illustrated in FIG. 5.

The light-emitting devices EDb can be attached to the bonding portion 511 of the stamp 510. The light-emitting devices EDb can include a first electrode Eb1, a light-emitting layer ELb, and a second electrode Eb2. The first electrode Eb1 of the light-emitting device EDb can be positioned closer to the lower substrate 310 than the second electrode Eb2. The second electrode Eb2 of the light-emitting device EDb can be positioned in contact with the bonding portion 511 of the stamp 510. The light-emitting layer ELb can be located between the first electrode Eb1 and the second electrode Eb2. Referring to FIG. 7, the light-emitting layer ELb can have a trapezoidal shape, but is not limited thereto.

Referring to FIG. 7 and FIG. 8, the stamp 510 can move toward the lower substrate 310. Accordingly, the light-emitting devices EDb can be electrically connected to the connection electrodes 421. Referring to FIG. 8, the first electrode Eb1 of the light-emitting device EDb can be electrically connected to the connection electrodes 421.

The stamp 510 can include power supply lines 530. The power supply lines 530 can be electrically connected to the second electrode Eb2 of the light-emitting device EDb. Referring to FIG. 8, the first electrode Eb1 of the light-emitting device EDb can be electrically connected to the connection electrodes 421, while the second electrode Eb2 can be electrically connected to the power supply lines 530 of the stamp 510.

After the light-emitting devices EDb are electrically connected to the connection electrodes 421, a voltage can be supplied to the light-emitting devices EDb. For example, the first electrode Eb1 of the light-emitting device EDb can receive a high-potential voltage through the connection electrodes 421, while the second electrode Eb2 of the light-emitting device EDb can receive a low-potential voltage, which is lower than the high-potential voltage, through the power supply line 530. However, the first electrode Eb1 of the light-emitting device EDb can alternatively receive a low-potential voltage through the connection electrodes 421, while the second electrode Eb2 of the light-emitting device EDb can receive a high-potential voltage, which is higher than the low-potential voltage, through the power supply lines 530.

After a high-potential voltage and a low-potential voltage are supplied to the light-emitting device EDb, the light-emitting device EDb can emit light. Referring to FIG. 5 and FIG. 7, the stamp 510 illustrated in FIG. 7 can include the reflective layer 521 illustrated in FIG. 5. The light emitted from the light-emitting device EDb can be reflected by the reflective layer 521 toward the lower part of the light-emitting device EDb. Accordingly, the intermediate material 431 can harden. Once the intermediate material 431 hardens, the position of the light-emitting device EDb can be fixed. For example, the position of the first electrode Eb1 of the light-emitting device EDb can be fixed, and likewise, the position of the light-emitting layer ELb of the light-emitting device EDb can be fixed. For example, the first electrode Eb1 of the light-emitting device EDb can be electrically connected to the connection electrodes 421 while maintaining a fixed position.

If the light-emitting device EDb itself is defective or if the first electrode Eb1 of the light-emitting device EDb is abnormally connected to the connection electrodes 421, the light-emitting device EDb may not emit light. As a result, the intermediate material 431 may not harden. The unhardened intermediate material 431 can undergo a repair process performed by an operator. After the repair process, the intermediate material 431 can still be present under the repaired light-emitting device EDb, but it can also be removed. For example, the repaired light-emitting device EDb may not overlap with the intermediate material 431.

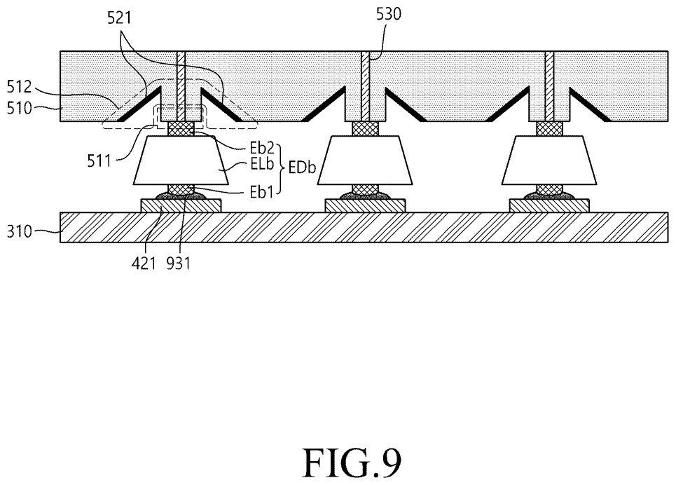

FIG. 9 is a cross-sectional view of the display panel 110 and the light-emitting device EDb according to embodiments of the present disclosure.

The lower substrate 310, connection electrodes 421, intermediate materials 931, light-emitting devices EDb, and stamp 510 illustrated in FIG. 9 can be the same as those illustrated in FIG. 7 and FIG. 8. Accordingly, repeated descriptions will be omitted.

Referring to FIG. 9, the first electrode Eb1 of the light-emitting devices EDb can be in contact with the intermediate material 931. In this case, the intermediate material 931 can include a conductive material. The first electrode Eb1 of the light-emitting devices EDb can be spaced apart from and not in direct contact with the connection electrodes 421. Although the first electrode Eb1 is not directly in contact with the connection electrodes 421, the intermediate material 931 can electrically connect the first electrode Eb1 to the connection electrodes 421.

The above description can be summarized as follows. The connection electrodes 421 can be disposed on the lower substrate 310. The intermediate material 931 can be disposed on the connection electrodes 421. The first electrode Eb1 of the light-emitting device EDb can be disposed on the intermediate material 931. The first electrode Eb1 of the light-emitting device EDb can overlap with the connection electrodes 421 while being spaced apart from them. The first electrode Eb1 of the light-emitting device EDb can overlap and be in contact with the intermediate material 931. The intermediate material 931 can include a conductive material, and the first electrode Eb1 can be electrically connected to the connection electrodes 421 through the intermediate material 931.

Meanwhile, referring to FIG. 7 to FIG. 8, when the intermediate material 431 is exposed to light, it can harden. Utilizing this characteristic of the intermediate material 431, it is possible to determine whether the light-emitting device EDb disposed on the intermediate material 431 is defective. However, the intermediate material 431 can also harden due to light emitted from a light-emitting device EDb that is not overlapping with the intermediate material 431. The features of a display device designed to prevent this will be described below.

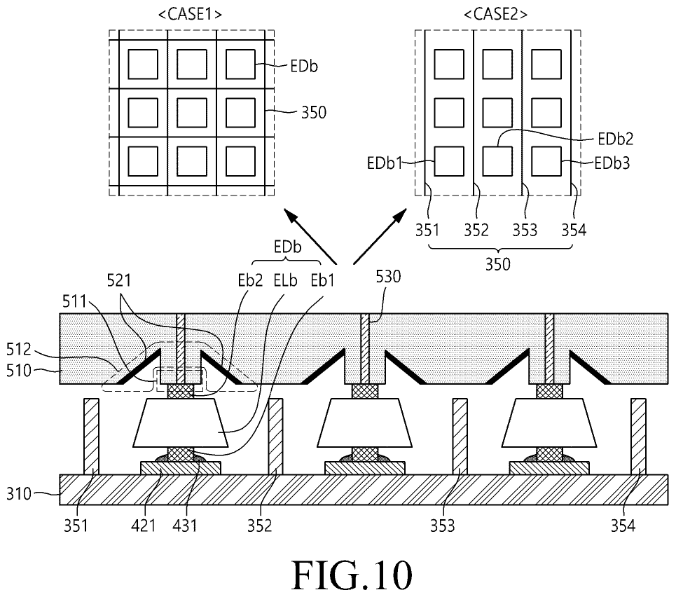

FIG. 10 is a cross-sectional view of the light-emitting device EDb and a barrier structure according to embodiments of the present disclosure.

Referring to FIG. 10, the light-emitting devices EDb can be disposed inside the barrier structure 350.

The barrier structure 350 can have a grid shape or a linear shape.

Referring to the first example (CASE 1) in FIG. 10, an example where the barrier structure 350 has a grid shape can be seen. The grid structure can have a #shape or a repeating square pattern. The light-emitting devices EDb can be located inside the #shape or the square pattern.

Referring to the second example (CASE 2) in FIG. 10, an example where the barrier structure 350 has a linear shape can be seen. Referring to FIG. 10, the barrier structure 350 can include a first barrier 351, a second barrier 352, a third barrier 353, and a fourth barrier 354. The barrier structure 350 can be formed to extend in the vertical direction. A first light-emitting device EDb1 can be located between the first barrier 351 and the second barrier 352. A second light-emitting device EDb2 can be located between the second barrier 352 and the third barrier 353. A third light-emitting device EDb3 can be located between the third barrier 353 and the fourth barrier 354.

When the barrier structure 350 is disposed around the light-emitting device EDb, the light emitted from the light-emitting device EDb can be reflected by the barrier structure 350. Referring to FIG. 10, the light emitted from the first light-emitting device EDb1 can be reflected by the barrier positioned to the right of the first light-emitting device EDb1, causing the light to initially travel to the right and then to the left. Similarly, the light emitted from the third light-emitting device EDb3 can be reflected by the barrier positioned to the left of the third light-emitting device EDb3, causing the light to initially travel to the left and then to the right.

For example, the light emitted from the first light-emitting device EDb1 can be reflected by the barrier structure 350 so that it is directed toward the upper side of the first light-emitting device EDb1. Similarly, the light emitted from the third light-emitting device EDb3 can be reflected by the barrier structure 350 so that it is directed toward the upper side of the third light-emitting device EDb3.

Referring to FIG. 10, the second light-emitting device EDb2 can be a defective light-emitting device that does not emit light, or it can be a light-emitting device that is not electrically connected to the connection electrodes 421. Accordingly, the intermediate material 431 positioned below the second light-emitting device EDb2 may not harden. In this case, the light emitted from the first light-emitting device EDb1 and the third light-emitting device EDb3 may not travel toward the intermediate material 431 positioned below the second light-emitting device EDb2 due to the barrier structure 350. For example, when the barrier structure 350 is positioned around the light-emitting devices EDb, the intermediate material 431 located beneath a defective light-emitting device EDb may not harden.

In other words, if the barrier structure 350 is not present, the intermediate material 431 positioned below the second light-emitting device EDb2 can still harden in some cases. However, when the barrier structure 350 is in place, the intermediate material 431 positioned below the second light-emitting device EDb2 may not harden.

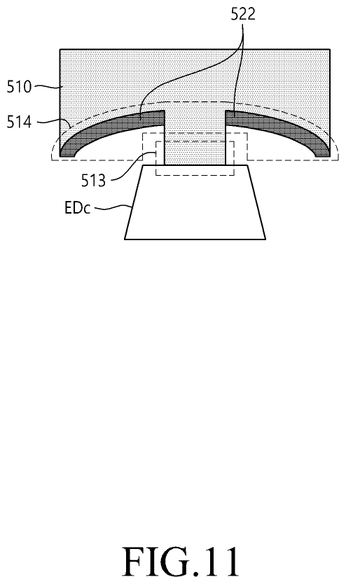

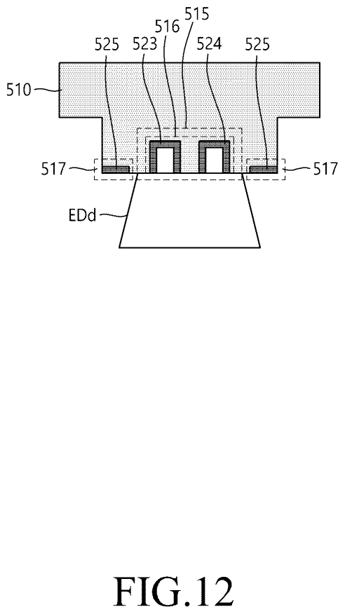

FIG. 11 and FIG. 12 are diagrams related to a reflective layer according to embodiments of the present disclosure.

Referring to FIG. 11, a stamp 510, a light-emitting device EDc attached to the stamp 510, and a reflective layer 522 positioned below the stamp 510 can be seen.

The light-emitting device EDc can be attached to a bonding portion 513 of the stamp 510.

The outer region of the bonding portion 513 can be a peripheral area 514. The peripheral area 514 can be a recessed groove-shaped area. A reflective layer 522 can be disposed in the peripheral area 514. Referring to FIG. 11, the reflective layer 522 can have a convex hemispherical shape. In this case, the hemispherical shape can be elliptical or can have a uniform curvature.

A cross-sectional view of the reflective layer 522 can be seen. Based on the cross-sectional view, the reflective layer 522 positioned to the right of the bonding portion 511 can have a shape that bends downward from the upper left to the lower right, and in this case, the reflective layer 522 can have a convex elliptical shape. Similarly, the reflective layer 522 positioned to the left of the bonding portion 511 can have a shape that bends downward from the upper right to the lower left, and in this case, the reflective layer 522 can also have a convex elliptical shape. Since the reflective layer 522 has a convex elliptical shape, the light emitted from the light-emitting device EDc can be more effectively directed toward the center of the light-emitting device EDc. For example, the reflective layer 522 illustrated in FIG. 11 can direct more light toward the light-emitting device EDc compared to the reflective layer 521 illustrated in FIG. 5.

Referring to FIG. 12, the bonding portion 515 of the stamp 510 can include a groove area 516. The groove area 516 of the bonding portion 515 of the stamp 510 can include multiple grooves. A plurality of internal reflective layers 523 and 524 can be disposed inside the multiple grooves. The plurality of internal reflective layers 523 and 524 can overlap with the light-emitting device EDd. Accordingly, the light emitted from the light-emitting device EDd can be directed upward, and the plurality of internal reflective layers 523 and 524 positioned above the light-emitting device EDd can reflect the light downward.

The bonding portion 515 of the stamp 510 can have a flat bottom surface. The bottom surface of the bonding portion 515 of the stamp 510 can be flat, and a light-emitting device EDd can be attached to a portion of the center of the bonding portion 515. The central area of the bonding portion 515 can include the attachment area for the light-emitting device EDd and a groove area 516. An external reflective layer 525 can be disposed in the outer peripheral area 517 of the center of the bonding portion 515. The external reflective layer 525 can reflect the light emitted from the light-emitting device EDd toward the lower part of the light-emitting device EDd.

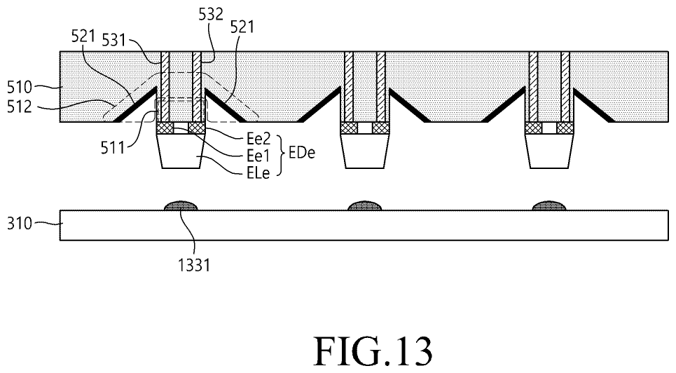

FIG. 13 is a diagram illustrating the reflective layer 521 according to embodiments of the present disclosure.

Referring to FIG. 13, an intermediate material 1331 can be disposed on the lower substrate 310. The characteristics of the intermediate material 1331 illustrated in FIG. 13 are the same as those of the intermediate materials 331 and 332 illustrated in FIG. 5.

The light-emitting device EDe can include a first electrode Ee1, a second electrode Ee2, and a light-emitting layer ELe. The structure of the light-emitting device EDe illustrated in FIG. 13 can be the same as that of the light-emitting device EDa illustrated in FIG. 5. For example, the light-emitting device EDe can be a flip-type light-emitting device.

The stamp 510 can include a first-type voltage supply line 531 and a second-type voltage supply line 532. The first-type voltage supply line 531 can be electrically connected to the first electrode Ee1 of the light-emitting device EDe. The second-type voltage supply line 532 can be electrically connected to the second electrode Ee2 of the light-emitting device EDe. When a high-potential voltage is supplied through the first-type voltage supply line 531, a low-potential voltage can be supplied through the second-type voltage supply line 532.

The light-emitting device EDe can be attached to the bonding portion 511 of the stamp 510. When the stamp 510 moves toward the lower substrate 310, the light-emitting layer ELe of the light-emitting device EDe can come into contact with the intermediate material 1331.

After the light-emitting layer ELe of the light-emitting device EDe contacts the intermediate material 1331, a voltage can be supplied through the first-type voltage supply line 531 and the second-type voltage supply line 532, causing the light-emitting device EDe to emit light. The light emitted from the light-emitting device EDe can be directed toward the intermediate material 1331, thereby hardening the intermediate material 1331. As the intermediate material 1331 hardens, the position of the light-emitting device EDe can be fixed.

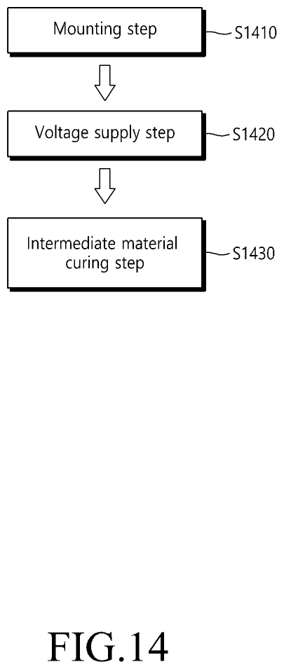

FIG. 14 is a flowchart illustrating a method of manufacturing a display device according to embodiments of the present disclosure.

Referring to FIG. 14, the method of manufacturing the display device can include a mounting step S1410, a voltage supply step S1420, and an intermediate material curing step S1430.

The mounting step S1410 can be a step in which the light-emitting device attached to the stamp comes into contact with the intermediate material, causing a portion of the light-emitting device to penetrate into the inner region of the intermediate material. In the mounting step S1410, the intermediate material can be in an uncured state. In the mounting step S1410, the light-emitting device can remain attached to the bonding portion of the stamp.

The voltage supply step S1420 can be a step in which voltage is supplied to the light-emitting device through the connection electrodes, causing the light-emitting device to emit light. As the light-emitting device operates, the light emitted from the light-emitting device can be directed toward the intermediate material.

The intermediate material curing step S1430 can be a step in which the intermediate material hardens upon receiving light emitted from the light-emitting device. As the intermediate material hardens, the position of the light-emitting device can be fixed. In the intermediate material curing step S1430, the reflective layer positioned at the lower part of the stamp can reflect the light emitted from the light-emitting device toward the region where the intermediate material is located. The reflective layer can be positioned in the outer peripheral area of the bonding portion or in the groove area of the bonding portion.

The display device according to embodiments of the present disclosure can be described as follows.

The embodiments of the present disclosure provide a display device comprising a substrate; a first connection electrode disposed on the substrate and including a metal material; a first light-emitting device disposed on the first connection electrode; a second connection electrode disposed on the substrate and including the metal material; a second light-emitting device disposed on the second connection electrode; a first intermediate material disposed on the first connection electrode, including a thermosetting material that hardens upon exposure to heat, and disposed in contact with a portion of the first light-emitting device; a second intermediate material disposed on the second connection electrode, including the thermosetting material, and disposed in contact with a portion of the second light-emitting device; and a barrier structure including a first portion positioned in a first outer region of the first light-emitting device, a second portion positioned in a second outer region of the second light-emitting device and extending parallel to the first portion, and a third portion positioned between the first and second light-emitting devices and extending parallel to the first portion.

The first light-emitting device can include a light-emitting layer, a first electrode disposed on one side of the light-emitting layer, and a second electrode disposed on the same side of the light-emitting layer, wherein the first electrode can be embedded in an inner side of the first intermediate material.

The first intermediate material can surround an outer edge of the first electrode, and the second intermediate material can surround an outer edge of the second electrode.

The first electrode can be electrically connected to the first connection electrode, and the second electrode can be electrically connected to the second connection electrode.

The first electrode can be in contact with the first connection electrode, and the second electrode can be in contact with the second connection electrode. The first and second intermediate materials can include a non-conductive material.

The first intermediate material can be disposed between the first electrode and the first connection electrode, and the second intermediate material can be disposed between the second electrode and the second connection electrode. The first and second intermediate materials can include a conductive material.

The first intermediate material can include at least one material selected from acrylate-based materials, epoxy-based materials, and polyurethane-based materials.

The position of the first light-emitting device can be fixed by the first intermediate material, and the position of the second light-emitting device can be fixed by the second intermediate material.

The first light-emitting device can include a first electrode overlapping the first connection electrode, a light-emitting layer disposed on the first electrode, and a second electrode disposed on the light-emitting layer, wherein the first electrode is embedded in an inner side of the first intermediate material, and the first intermediate material surrounds an outer edge of the first electrode.

The first electrode can be electrically connected to the first connection electrode.

The first electrode can be in contact with the first connection electrode, and the first intermediate material can include a non-conductive material.

The first intermediate material can be disposed between the first electrode and the first connection electrode, and the first intermediate material can include a conductive material.

The barrier structure can include a light-reflecting material.

The barrier structure can include a light-absorbing material.

The barrier structure can be positioned to surround the first and second light-emitting devices.

The first portion can extend to be connected to the second portion, and the third portion can extend to be connected to the second portion.

The second portion can be spaced apart from the first portion and the third portion.

The first light-emitting device can include a light-emitting layer, a first electrode disposed on one side of the light-emitting layer, and a second electrode disposed on the same side of the light-emitting layer, wherein the light-emitting layer is embedded in an inner side of the first intermediate material.

Accordingly, the display device can securely fix the light-emitting device. In addition, defective light-emitting devices can be replaced through a repair process. Furthermore, process optimization can be achieved.

The embodiments of the present disclosure provide a method of manufacturing a display device, including a mounting step in which a light-emitting device attached to a stamp comes into contact with an intermediate material, and a portion of the light-emitting device is embedded in an inner side of the intermediate material, a voltage supply step in which voltage is supplied to the light-emitting device through a connection electrode, and the light-emitting device emits light, and an intermediate material curing step in which the intermediate material hardens upon receiving light emitted from the light-emitting device.

In the mounting step, the light-emitting device can be attached to a bonding portion of the stamp. In the intermediate material curing step, a reflective layer positioned below the stamp can reflect the light emitted from the light-emitting device toward the region where the intermediate material is positioned. The reflective layer can be positioned in an outer region of the bonding portion or in a groove area of the bonding portion.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present invention. The above description and the accompanying drawings provide an example of the technical idea of the present invention for illustrative purposes only. For example, the disclosed embodiments are intended to illustrate the scope of the technical idea of the present invention.

What is claimed is:

1. A display device comprising:
a substrate;
a first connection electrode disposed on the substrate and including a metal material;
a first light-emitting device disposed on the first connection electrode;
a second connection electrode disposed on the substrate and including the metal material;
a second light-emitting device disposed on the second connection electrode;
a first intermediate material disposed on the first connection electrode, the first intermediate material including a thermosetting material that hardens upon exposure to heat or light, and disposed in contact with a portion of the first light-emitting device;
a second intermediate material disposed on the second connection electrode, the second intermediate material including the thermosetting material, and disposed in contact with a portion of the second light-emitting device; and
a barrier structure including a first portion positioned in a first outer region of the first light-emitting device, a second portion positioned in a second outer region of the second light-emitting device and extending parallel to the first portion, and a third portion positioned between the first and second light-emitting devices and extending parallel to the first portion.

2. The display device according to claim 1,
wherein the first light-emitting device comprises:
a first light-emitting layer;
a first electrode disposed on one side of the first light-emitting layer; and
a second electrode disposed on the same one side of the first light-emitting layer,
wherein the first electrode is embedded in an inner side of the first intermediate material,
wherein the second light-emitting device comprises:
a second light-emitting layer;
a third electrode disposed on the second light-emitting layer; and
a fourth electrode disposed together with the third electrode on the second light-emitting layer, and
wherein the third electrode is embedded in an inner side of the second intermediate material.

3. The display device according to claim 2, wherein the first intermediate material surrounds an outer edge of the first electrode, and the second intermediate material surrounds an outer edge of the third electrode.

4. The display device according to claim 3, wherein the first electrode is electrically connected to the first connection electrode; and the third electrode is electrically connected to the second connection electrode.

5. The display device according to claim 4,
wherein the first electrode is in contact with the first connection electrode,
wherein the third electrode is in contact with the second connection electrode, and
wherein the first and second intermediate materials include a non-conductive material.

6. The display device according to claim 4,
wherein the first intermediate material is disposed between the first electrode and the first connection electrode,
wherein the second intermediate material is disposed between the third electrode and the second connection electrode, and
wherein the first and second intermediate materials include a conductive material.

7. The display device according to claim 1, wherein the first intermediate material comprises at least one material selected from acrylate-based materials, epoxy-based materials, and polyurethane-based materials.

8. The display device according to claim 1,
wherein a position of the first light-emitting device is fixed by the first intermediate material, and
wherein a position of the second light-emitting device is fixed by the second intermediate material.

9. The display device according to claim 1,
wherein the first light-emitting device comprises:
a first electrode overlapping the first connection electrode;
a light-emitting layer disposed on the first electrode; and
a second electrode disposed on the light-emitting layer, and
wherein the first electrode is embedded in an inner side of the first intermediate material, and the first intermediate material surrounds an outer edge of the first electrode.

10. The display device according to claim 9, wherein the first electrode is electrically connected to the first connection electrode.

11. The display device according to claim 10, wherein the first electrode is in contact with the first connection electrode, and the first intermediate material includes a non-conductive material.

12. The display device according to claim 10, wherein the first intermediate material is disposed between the first electrode and the first connection electrode, and the first intermediate material includes a conductive material.

13. The display device according to claim 1, wherein the barrier structure includes a light-reflecting material.

14. The display device according to claim 1, wherein the barrier structure includes a light-absorbing material.

15. The display device according to claim 1, wherein the barrier structure is positioned to surround the first and second light-emitting devices.

16. The display device according to claim 1, wherein the first portion of the barrier structure extends to be connected to the second portion of the barrier structure, and the third portion of the barrier structure extends to be connected to the second portion of the barrier structure.

17. The display device according to claim 1, wherein the second portion of the barrier structure is spaced apart from the first and third portions of the barrier structure.

18. The display device according to claim 1,
wherein the first light-emitting device comprises:
a light-emitting layer;
a first electrode disposed on one side of the light-emitting layer; and
a second electrode disposed on the same one side of the light-emitting layer, and
wherein the light-emitting layer is embedded in an inner side of the first intermediate material.

19. A method of manufacturing a display device, the method comprising:
a mounting step in which a light-emitting device attached to a stamp comes into contact with an intermediate material, and a portion of the light-emitting device is embedded in an inner side of the intermediate material;
a voltage supply step in which a voltage is supplied to the light-emitting device through a connection electrode, so that the light-emitting device emits light; and
an intermediate material curing step in which the intermediate material hardens upon receiving the light emitted from the light-emitting device.

20. The method of manufacturing the display device according to claim 19,
wherein in the mounting step, the light-emitting device is attached to a bonding portion of the stamp;
wherein in the intermediate material curing step, a reflection layer positioned below the stamp reflects the light emitted from the light-emitting device toward a region where the intermediate material is positioned; and
wherein the reflection layer is positioned in an outer region of the bonding portion or in a groove area of the bonding portion of the stamp.
